(19) United States
(12) Patent Application Publication
(10) Pub. No.: US 2003/0164290 A1
(43) Pub. Date: Sep. 4, 2003

(54) Method of forming an ITO layer on a heat-sensitive substrate

(76) Inventors: Chi-Lin Chen, Hsinchu (TW); Tsung-Neng Liao, Taichung (TW)

Correspondence Address: BIRCH STEWART KOLASCH & BIRCH, PO BOX 747, FALLS CHURCH, VA, 22040-0747, US

(21) Appl. No.: 10/301,795

(22) Filed: Nov. 22, 2002

(30) Foreign Application Priority Data
Mar. 1, 2002 (TW) 091103862

(51) Int. Cl. C23C 14/32

(52) U.S. Cl. 204/192.29; 204/192.14; 204/192.26

(57) ABSTRACT

A method of forming an indium tin oxide (ITO) layer on a heat-sensitive substrate. An amorphous ITO layer is formed on the substrate by a sputtering process, wherein the temperature of the sputtering process is controlled at room temperature and, in situ, hydrogen gas with a flow rate of 1˜5 sccm is introduced in the sputtering process. Part of the amorphous ITO layer is removed by an oxalic acid solution to form an amorphous ITO pattern on the substrate. A heat treatment whose temperature is below 150° C. is performed to turn the amorphous ITO pattern into a crystalline ITO layer. Thus, a crystalline and flat ITO layer can be formed on the heat-sensitive substrate.

### BACKGROUND OF THE INVENTION

1. Field of the Invention

The present invention relates to a method of forming a layer of Indium Tin Oxide (ITO), and more particularly, to a method of forming an ITO layer on a heat-sensitive substrate.

2. Description of the Related Art

A transparent conductive layer of Indium Tin Oxide (ITO) is practically applied to the fabrication of a contact of contact panel, an electrode of liquid crystal display (LCD), and an electrode of organic electro-luminescent display (OELD). To obtain an ITO layer having a low resistance and a high transparency, a crystalline ITO layer is commonly used. In the traditional process, the crystalline ITO layer is deposited on a glass substrate by a high temperature process whose temperature is greater than 200° C.

However, because of the high temperature process, the traditional method is not suitable for forming a crystalline ITO layer on a heat-resistant substrate, such as a plastic substrate whose glass transformation temperature is lower than 150° C. That is, the tradition process cannot meet the requirements for the plastic display fabrication.

Additionally, when the high temperature process is used to deposit the crystalline ITO layer on a substrate, the crystalline ITO layer having a rough surface (Rₘₛ>1 nm) is formed. Thus, a planarization such as a chemical mechanical polishing (CMP) is needed to smooth the surface of the crystalline ITO layer. This causes high production costs and an inefficient process. Moreover, when the crystalline ITO layer is patterned with an aqua regia etchant (H₂SO₄+HNO₃), the aqua regia etchant can damage the other metal layers so as to reduce the reliability of the product.

Thus, a method of forming an ITO layer solving the aforementioned problems is called for.

### SUMMARY OF THE INVENTION

The object of the present invention is to provide a method of forming an ITO layer.

Another object of the present invention is to provide a method of using a low temperature sputtering process and a low temperature heat treatment to form a crystalline ITO layer on a heat-sensitive substrate.

Yet another object of the present invention is to provide a method of forming a crystalline and flat ITO layer without performing any extra planarization.

To achieve these objects, the present invention provides a method of forming an ITO layer on a heat-sensitive substrate. An amorphous ITO layer is formed on the substrate by a sputtering process, wherein the temperature of the sputtering process is controlled at room temperature and, in situ, hydrogen gas whose flow rate is 1˜5 sccm is introduced in the sputtering process. Part of the amorphous ITO layer is removed by an oxalic acid solution to form an amorphous ITO pattern on the substrate. A heat treatment whose temperature is below 150° C. is performed to convert the amorphous ITO pattern to a crystalline ITO layer.

The present invention improves on the prior art in that the present method uses a low temperature sputtering process and, in situ, introduces an optimal amount of hydrogen gas into the sputtering process to form the amorphous ITO layer. The amorphous ITO layer is crystallized by a low temperature heat treatment. Thus, the present invention is suitable for fabricating plastic products, such as plastic displays.

### BRIEF DESCRIPTION OF THE DRAWINGS

The present invention can be more fully understood by reading the subsequent detailed description in conjunction with the examples and references made to the accompanying drawings, wherein:

FIGS. 1˜5 are schematic diagrams according to an embodiment of the present invention.

### DETAILED DESCRIPTION OF THE INVENTION

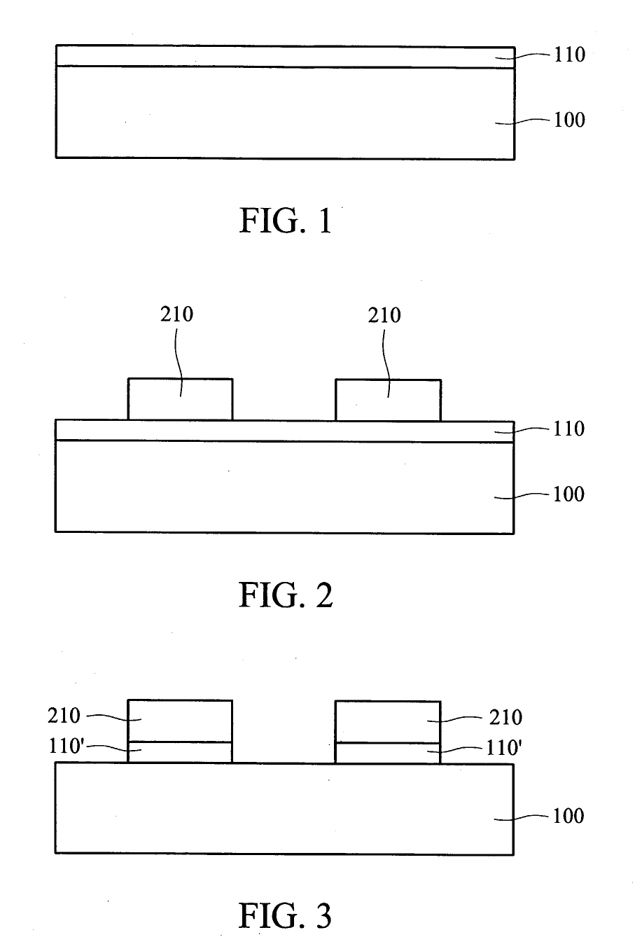

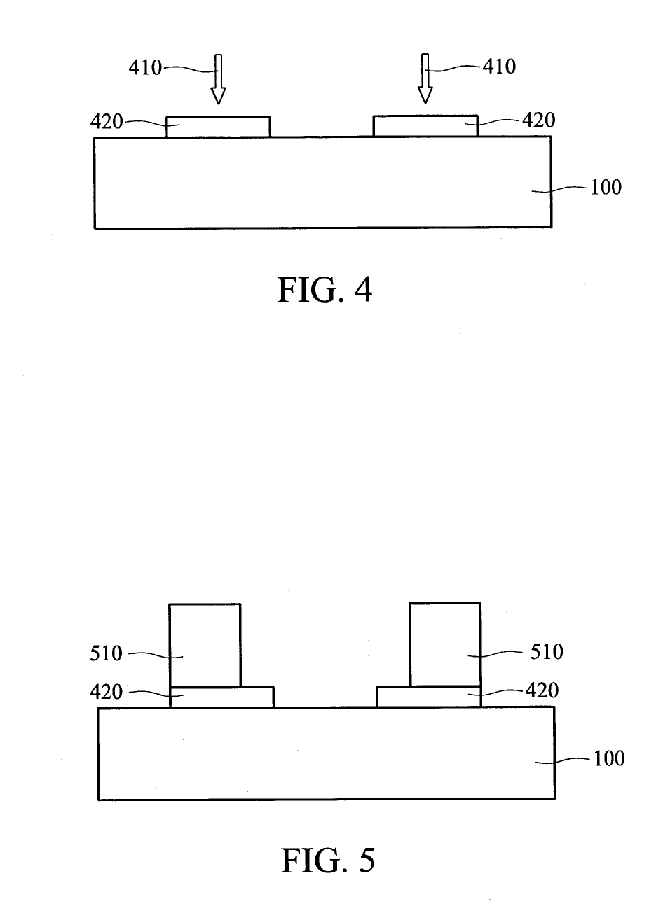

The present invention provides a method of forming an ITO layer that is suitable for fabricating the products, such as thin film transistor (TFT), liquid crystal display (LCD), and organic light emitting diode (OLED). Hereinafter, as a demonstrative application, the method of forming an ITO layer is applied to the formation of a transparent electrode in OLED. FIGS. 1˜5 are schematic diagrams according to an embodiment of the present invention.

In FIG. 1, an amorphous ITO layer 110 of 1000˜1500 Å thickness is formed on a substrate 100 by a sputtering process, wherein the temperature of the sputtering process is controlled at 10˜50° C. and, in situ, hydrogen gas with a flow rate of 1˜5 sccm is introduced into the sputtering process. The substrate 100 is transparent. The substrate 100 can be a heat-sensitive substrate such as a plastic layer, and also can be an insulating layer such as a SiO₂ layer. Moreover, at least one transistor structure (not shown, such as a TFT or a MOS structure) can be included in the substrate 100. The operating conditions of the sputtering process are controlled at 10˜50° C. and introduced with 1˜5 sccm of hydrogen gas, so as to prevent the amorphous ITO layer 110 from crystallizing. It is preferred that the temperature of the sputtering process be controlled at room temperature (about 25° C.) and introduced with about 3 sccm of hydrogen gas. Thus, the amorphous ITO layer 110 having about 600˜800 μΩ·cm for resistance, about 70˜80% for transparency and about 0.2˜0.3 nm for roughness (Rₘₛ) can be formed on the substrate 100. Additionally, the sputtering process is typically introduced with argon gas and/or oxygen gas.

In FIGS. 2˜3, for example, using a conventional photolithography process, a resist pattern 210 is formed on part of the amorphous ITO layer 110. Using the resist pattern 210 as a mask, part of the amorphous ITO layer 110 is etched by, for example, an oxalic acid solution ((COOH)₂) to expose part of the substrate 100 and form an amorphous ITO pattern 110′ on part of the substrate. In this example, the hard baking temperature of the photolithography process is preferably kept below 110° C., because the higher temperature of hard baking may cause a micro-crystalline phenomenon on the surface of the amorphous ITO layer 110 and the oxalic acid solution cannot completely remove the crystalline area of the ITO layer.

In FIG. 4, the resist pattern 210 is stripped by, for example, a KOH etchant. A heat treatment 410 serving as an annealing is performed to turn the amorphous ITO pattern 110′ into a crystalline ITO layer 420, wherein the temperature of the heat treatment 410 is controlled at 100˜150° C. Preferably, the temperature of the heat treatment 410 is controlled at 140° C. As a demonstrative example, after performing the heat treatment 410 of 140° C. for 30 minutes, the crystalline ITO layer 420 having about 200 μΩ·cm for resistance, above 90% for transparency and about 0.4˜0.5 nm for roughness (Rₘₛ) is formed on the substrate 100. Because of the low roughness, the flat ITO layer is not needed to perform any extra planarization after the heat treatment 410.

Moreover, an oxygen (O₂) plasma treatment can be performed on the crystalline ITO layer 420 in order to enhance the work function of the crystalline ITO layer 420. Additionally, as shown as the FIG. 5, an organic light emitting diode (OLED) structure 510 is formed on the crystalline ITO layer 420, wherein the crystalline ITO layer 420 serves as a transparent electrode of the OLED structure 510.

Thus, the present invention provides a method of forming an indium tin oxide (ITO) layer, especially, forming an ITO layer on a heat-sensitive substrate. The present invention performed under a low temperature ambient is very suitable for fabricating plastic display products. Additionally, the ITO layer according to the present invention has a flat surface without performing any extra planarization, thereby decreasing the production cost.

Finally, while the invention has been described by way of example and in terms of the above, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A method of forming an indium tin oxide (ITO) layer, comprising the steps of:
providing a substrate;
performing a sputtering process to form an amorphous ITO layer on the substrate, wherein the temperature of the sputtering process is controlled at 10˜50° C. and, in situ, hydrogen gas is introduced in the sputtering process;
using an etching solution to remove part of the amorphous ITO layer to form an amorphous ITO pattern on the substrate; and
performing a heat treatment to turn the amorphous ITO pattern into a crystalline ITO layer, wherein the temperature of the heat treatment is controlled at 100˜150° C.

2. The method according to claim 1, further comprising the step of:
performing an oxygen plasma treatment on the crystalline ITO layer.

3. The method according to claim 2, further comprising the step of:
forming an organic light emitting diode (OLED) structure on the crystalline ITO layer, wherein the crystalline ITO layer serves as a transparent electrode of the OLED structure.

4. The method according to claim 1, wherein the material of the substrate is a plastic material.

5. The method according to claim 1, wherein the material of the substrate is an insulating material.

6. The method according to claim 5, wherein the substrate comprises a transistor structure.

7. The method according to claim 5, wherein the insulating material is SiO₂.

8. The method according to claim 1, wherein the thickness of the substrate is 1000˜1500 Å.

9. The method according to claim 1, wherein the temperature of the sputtering process is controlled at room temperature (about 25° C.).

10. The method according to claim 1, wherein the flow rate of hydrogen gas is controlled at 1˜5 sccm.

11. The method according to claim 10, wherein the flow rate of hydrogen gas is controlled at 3 sccm.

12. The method according to claim 1, further comprising the step of:
introducing argon (Ar) gas in the sputtering process.

13. The method according to claim 1, further comprising the step of:
introducing oxygen (O₂) gas in the sputtering process.

14. The method according to claim 1, wherein the etching solution is oxalic acid.

15. The method according to claim 1, wherein the temperature of the heat treatment is controlled at 140° C.

16. The method according to claim 1, wherein, after the heat treatment, the ITO layer is not needed to perform a planarization.
